(19) United States
(12) Patent Application Publication
(10) Pub. No.: US 2010/0309941 A1
(43) Pub. Date: Dec. 9, 2010

(54) SEMICONDUCTOR LASER DEVICE

(76) Inventors: Keiji Ito, Hyogo (JP); Isao Kidoguchi, Hyogo (JP); Toru Takayama, Hyogo (JP)

Correspondence Address: MCDERMOTT WILL & EMERY LLP, 600 13TH STREET, NW, WASHINGTON, DC, 20005-3096, US

(21) Appl. No.: 12/715,125

(22) Filed: Mar. 1, 2010

(30) Foreign Application Priority Data
Jun. 8, 2009 (JP) 2009-137419

(51) Int. Cl. H01S 5/343; H01S 5/40; H01S 5/34

(52) U.S. Cl. 372/45.01; 372/50.121; 977/755

(57) ABSTRACT

A semiconductor laser device includes a first semiconductor laser element and a second semiconductor laser element different in oscillation wavelength from the first semiconductor laser element, both formed on a substrate. The first and second semiconductor laser elements have a cavity length of 1500 μm or more, and each have an n-type cladding layer made of In_{y}(Ga₁₋ₓ₁Alₓ₁)_{1-y}P (0<x1<1, 0<y<1) and a p-type cladding layer made of In_{y}(Ga₁₋ₓ₂Alₓ₂)_{1-y}P (0<x2<1, 0 <y<1). An active layer is made of Al_{z}Ga_{1-z}As (0≦z≦1) and includes only one well layer.

### CROSS-REFERENCE TO RELATED APPLICATION

This application claims priority to Japanese Patent Application No. 2009-137419 filed on Jun. 8, 2009, the disclosure of which including the specification, the drawings, and the claims is hereby incorporated by reference in its entirety.

### BACKGROUND

The technology disclosed herein relates to a semiconductor laser device, and more particularly to a monolithic dual-wavelength laser device that outputs laser beams having two different wavelengths from one chip.

A monolithic dual-wavelength laser device (hereinafter simply referred to as a dual-wavelength laser device) is a semiconductor laser device in which a 660 nm-band semiconductor laser element for recording on DVDs (digital versatile discs) (hereinafter referred to as a DVD laser element) and a 780 nm-band semiconductor laser element for LightScribe labeling and recording on CDs (compact discs) (hereinafter referred to as a CD laser element) are integrated on one element. In such a dual-wavelength laser device, since two laser elements can be formed simultaneously on one element, the degree of parallelism between two laser beams and the distance therebetween can be controlled with considerably high precision, compared with the case of forming two laser elements separately and then mounting them side by side on a substrate.

In the dual-wavelength laser device, because of constraints in the fabrication method thereof, optimization of the rated output must be made individually for the cavity of the DVD laser element and the cavity of the CD laser element under the condition that the cavities of these laser elements have the same configuration, as described in Japanese Patent Publication No. 2005-167218, for example.

A semiconductor material constituting the DVD laser element is susceptible to heat dissipation compared with a semiconductor material constituting the CD laser element, and hence likely to cause decrease in output that results from gain saturation. For this reason, the optimum cavity length of the DVD laser element is longer than that of the CD laser element.

For example, the minimum output required for DVD dual-layer recording is 300 mW or more, which is output from the DVD laser element pulse-driven under the environment of a case temperature of 85° C. To attain this, the cavity length of the duel-wavelength laser device should preferably be 1500 μm or more, more preferably 2000 μm or more. In terms of the CD laser element, however, this length largely deviates from its optimum cavity length, thereby causing increase in threshold current and decrease in the efficiency of conversion of a current injected into an active layer to light. In particular, rise in element temperature, which results from increase in power consumption, raises a serious problem in enhancing the quality of LightScribe labeling. In the conventional CD recording, the maximum reachable temperature of the CD laser element was 85° C. In LightScribe labeling, however, the maximum reachable temperature of the CD laser element is as high as 95° C. This rise in maximum reachable temperature significantly degrades the reliability of the duel-wavelength laser device.

Japanese Patent Publication No. 2005-167218 mentioned above describes a method by which the optimum cavity length can be set individually for red and infrared laser elements of a dual-wavelength laser device. In this method, an end facet window structure that blocks current injection into an active layer is adopted in a region of one or both of the laser elements ranging from an end facet toward the cavity center, thereby to control the effective cavity length.

### SUMMARY

As described above, to implement a high-output CD laser element operating stably for a long time in a dual-wavelength laser device having a long cavity, the power consumption of the CD laser element must be reduced.

If the heat dissipation of a laser device exceeds a predetermined value due to increase in the power consumption of the laser device, a crack may occur in a plastic lens placed near the laser device for condensing laser light.

Also, if the output of a drive circuit for supplying a current to the laser device increases, the junction temperature of a semiconductor element constituting the drive circuit may become near 150° C., causing a serious problem of degradation in the life of the drive circuit.

In the dual-wavelength laser device described in Japanese Patent Publication No. 2005-167218, the following problem occurs. The change in refractive index that results from current injection differs between a region into which the current is injected and a region into which no current is injected. Hence, if the proportion of the non-current-injected region to the current-injected region is high, light propagating in the cavity may give rise to mode competition, causing instability of the operation.

In a CD laser element having an active layer made of Al_{z}Ga_{1-z}As (0≦z<1) and a cladding layer made of In_{y}(Ga₁₋ₓAlₓ)_{1-y}P (0<x<1, 0<y<1), Japanese Patent Publication No. 2002-305357 and Japanese Patent Publication No. 2001-057462, for example, describe techniques in which, while the simplicity of the fabrication process as a merit of the dual-wavelength laser device is enjoyed, the stripe is narrowed to obtain a merit of improving the kink level, and moreover, increase in power consumption can be suppressed. However, no detailed examination has been made on such techniques.

Specifically, Japanese Patent Publication No. 2002-305357 describes that in a 780 nm-band semiconductor laser element having a cladding layer made of In_{0.5}(Ga_{1-c}Al_{c})_{0.5}P and an active layer including an AlGaAs quantum well, by setting c at 0≦c≦0.2 in the composition of the cladding layer, the mobility in the cladding layer is enhanced, permitting increase in the output of the CD laser element.

However, in the dual-wavelength laser device, when c is set at 0≦c≦0.2 in the composition of the cladding layer, it is unable to enjoy the simplicity of the fabrication process while maintaining the performance of the DVD laser element and the CD laser element. The reason for this is as follows.

To ensure the output of the DVD laser element at 300 mW or more under a high temperature of 85° C., the cladding layer of the DVD laser element is formed of In_{y}(Ga₁₋ₓAlₓ)_{1-y}P (0<x<1, 0<y<1). Moreover, in conjunction with the band barrier between the active layer and the cladding layer, to suppress decrease in gain that results from increase in the overflow of carriers, x must be 0.6≦x≦0.8.

Ridges that are to be the waveguides of the DVD laser element and the CD laser element must be formed simultaneously by one-time etching. With this simultaneous formation, the spacing between the two ridges and the degree of parallelism therebetween can be controlled with the precision of a photomask. In this case, the difference in value x in the composition In_{y}(Ga₁₋ₓAlₓ)_{1-y}P (0<x<1, 0<y<1) between the cladding layer of the DVD laser element and the cladding layer of the CD laser element must be at least 0.05 or less.

Also, both the DVD laser element and the CD laser element have a window structure for suppressing end facet degradation. Such window structures can be formed simultaneously by setting x in the compositions of the cladding layers of the CD laser element and the DVD laser element within the above range, and hence the fabrication process can be simplified.

Consequently, to enjoy the simplicity of the fabrication process of the dual-wavelength laser device while suppressing decrease in the gain of the DVD laser element, 0.6≦x≦0.8 must be satisfied also in the composition of the cladding layer of the CD laser element. Accordingly, the effect described in Japanese Patent Publication No. 2002-305357 is not obtained for the dual-wavelength laser device.

Japanese Patent Publication No. 2001-057462 describes that in a 780 nm-band laser having a cladding layer made of In_{y}(Ga₁₋ₓAlₓ)_{1-y}P (0<x≦1, 0<y≦1) and an active layer including an Al_{z}Ga_{1-z}As (0≦z<1) quantum well, by forming the active layer as a bulk structure having a film thickness of 0.01 μm to 0.05 μm, the height of the band gap discontinuity occurring at the interface between the cladding layer and the active layer can be reduced, permitting improvement in operating current and operating voltage.

However, in a dual-wavelength laser device having a long cavity, increase in threshold voltage that results from the increase in the thickness of the active layer greatly influences the device. Therefore, in high-output, high-temperature operation, the heat saturation level significantly decreases, failing to obtain the effect of reducing power consumption.

As described above, all of the conventional techniques have difficulty in obtaining a high-output dual-wavelength laser device in which power consumption can be sufficiently reduced.

According to a semiconductor laser device of an illustrative embodiment of the present invention, a dual-wavelength semiconductor laser device with high reliability in which power consumption during high output and during high-temperature operation can be reduced can be implemented.

To attain the above object, the semiconductor laser device of an example of the present invention includes: a first semiconductor laser element; and a second semiconductor laser element different in oscillation wavelength from the first semiconductor laser element, formed in a same substrate as the first semiconductor laser element, wherein the first semiconductor laser element and the second semiconductor laser element have the same cavity length, which is 1500 μm or more, the first semiconductor laser element and the second semiconductor laser element each have an n-type cladding layer made of In_{y}(Ga₁₋ₓ₁Alₓ₁)_{1-y}P (0<x1<1, 0<y<1) and a p-type cladding layer made of In_{y}(Ga₁₋ₓ₂Alₓ₂)_{1-y}P (0<x2<1, 0<y<1), and the first semiconductor laser element has a first active layer that is made of Al_{z}Ga_{1-z}As (0≦z≦1), is placed between the n-type cladding layer and the p-type cladding layer, and includes only one first well layer.

With the configuration described above, in which the first active layer includes only one first well layer and the cavity length of the first semiconductor laser element is 1500 μm or more, the threshold current can be reduced compared with a configuration of the first active layer including a plurality of well layers, and hence the power consumption can be reduced even under high output. Also, since the heat dissipation can be reduced, the reliability can be improved even under a high-temperature condition compared with the conventional semiconductor laser elements. Hence, the first semiconductor laser element of the semiconductor laser device can be used, not only as a CD laser element, but also as a laser element for LightScribe labeling with improved reliability.

As described above, according to the present invention, a dual-wavelength laser device that is compatible to both DVD dual-layer recording and LightScribe labeling, can reduce the power consumption of the first semiconductor laser element, and has high reliability can be provided.

### BRIEF DESCRIPTION OF THE DRAWINGS

FIG. 1 is a cross-sectional view of a dual-wavelength laser device of Embodiment 1 of the present invention as viewed from the front (light emerging) end facet side.

FIG. 2A is a view showing measurement results of the relationship between the cavity length and the threshold voltage observed when elements A and B are pulse-driven under the environment of a case temperature of 95° C., and FIG. 2B is a view showing measurement results of the relationship between the operating current and the cavity length observed when the elements A and B are pulse-driven to produce a light output of 400 mW under the environment of a case temperature of 95° C.

FIG. 3 is a view showing simulation results of the relationship between the well layer thickness and the threshold current observed when the elements are pulse-driven under the environment of a case temperature of 95° C.

FIG. 4 is a view showing noise characteristics of the elements A and B.

FIG. 5 is a cross-sectional view of a dual-wavelength laser device of Embodiment 2 of the present invention as viewed from the front end facet side.

FIG. 6A is a view showing measurement results of the relationship between the cavity length and the threshold voltage observed when elements C and D are pulse-driven under the environment of a case temperature of 95° C., and FIG. 6B is a view showing measurement results of the relationship between the operating current and the cavity length observed when the elements C and D are pulse-driven to produce a light output of 400 mW under the environment of a case temperature of 95° C.

FIG. 7 is a view showing the relationship between the critical cavity length at which the power consumption of a CD laser element in Embodiment 2 becomes lower than that of a CD laser element of a comparative example and the impurity concentration of an n-type second cladding layer.

### DETAILED DESCRIPTION

Embodiments of the present invention will be described with reference to the accompanying drawings.

### Embodiment 1

### Configuration of Dual-Wavelength Laser Device

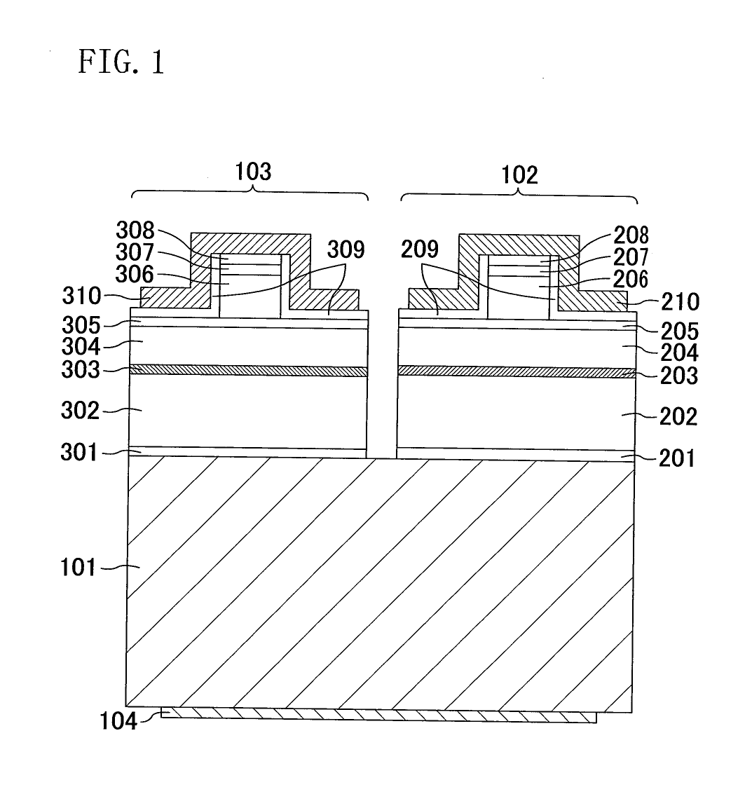

FIG. 1 is a cross-sectional view of a dual-wavelength laser device of Embodiment 1 of the present invention as viewed from the front (light emerging) end facet side. As shown in FIG. 1, the dual-wavelength laser device of this embodiment includes a DVD laser element (second semiconductor laser element) 102 and a CD laser element (first semiconductor laser element) 103 formed adjacent to each other on the top of a substrate 101 made of n-type GaAs.

In the DVD laser element 102, formed sequentially on the top of the n-type GaAs substrate 101 are a buffer layer 201 made of n-type GaAs, an n-type cladding layer 202 made of n-type In_{0.5}(Ga_{0.32}Al_{0.68})_{0.5}P, an active layer 203, a p-type first cladding layer 204 made of p-type In_{0.5}(Ga_{0.3}Al_{0.7})_{0.5}P, an etching stop layer 205 made of p-type GaInP, a p-type second cladding layer 206 made of p-type In_{0.5}(Ga_{0.3}Al_{0.7})_{0.5}P, an intermediate layer 207 made of p-type GaInP, and a contact layer 208 made of p-type GaAs.

The active layer 203 has a quantum well structure made of GaInP/In_{0.5}(Ga_{0.5}Al_{0.5})_{0.5}P of which the oscillation wavelength is 660 nm. The thickness of a well layer made of GaInP is 6.5 nm, for example, and the thickness of a barrier layer made of In_{0.5}(Ga_{0.5}Al_{0.5})_{0.5}P is 4 nm, for example. The number of well layers is 3, for example.

The n-type cladding layer 202 has a thickness of 2.7 μm, for example, and an impurity concentration of about 5×10¹⁷ cm⁻³. The p-type first cladding layer 204 has a thickness of 0.17 μm and an impurity concentration of about 5×10¹⁷ cm⁻³. The p-type second cladding layer 206 has a thickness of 1.5 μm, for example, and an impurity concentration of about 1×10¹⁸ cm⁻³.

The p-type second cladding layer 206 has a trapezoidal ridge that is to be a waveguide, extending straight in a direction parallel to the light emerging direction as viewed from top. The height of the ridge (distance from the p-type GaAs contact layer 208 to the p-type GaInP etching stop layer 205) is 1.5 μm, for example, and the width of the ridge is 3.5 μm, for example.

A current blocking layer 209 made of Si₃N₄ is formed on both side faces of the ridge and on the top of the etching stop layer 205, thereby to allow a current to flow only in the ridge.

A p-type electrode 210 constructed of a multilayer structure of Ti/Pt/Au layers, for example, is formed on the top of the p-type GaAs contact layer 208 and on the current blocking layer 209 to be in contact with these layers.

On the back of the n-type GaAs substrate 101, formed is an n-type electrode 104 constructed of a multilayer structure of AuGe/Ni/As layers, for example. The n-type electrode 104 is shared by the DVD laser element 102 and the CD laser element 103.

As the distance between the front end facet (light emerging end facet) and rear end facet of the active layer 203 (cavity length), 1500 μm or more is enough to ensure a sufficient output (e.g. 300 mW or more) for the DVD laser element 102, but 1700 μm or more is more preferred as will be discussed later. In this embodiment, the cavity length is set at four variations: 1500 μm, 2000 μm, 2200 μm. Light confinement is configured to have a horizontal spread angle of 9° and a vertical spread angle of 16°. Light generated in the active layer 203 emerges from the front end facet of the semiconductor layers including the active layer.

In the CD laser element 103, formed sequentially on the top of the n-type GaAs substrate 101 are a buffer layer 301 made of n-type GaAs, an n-type cladding layer 302 made of n-type In_{0.5}(Ga_{0.32}Al_{0.68})_{0.5}P, an active layer 303, a p-type first cladding layer 304 made of p-type In_{0.5}(Ga_{0.3}Al_{0.7})_{0.5}P, an etching stop layer 305 made of p-type GaInP, a p-type second cladding layer 306 made of p-type In_{0.5}(Ga_{0.3}Al_{0.7})_{0.5}P, an intermediate layer 307 made of p-type GaInP, and a contact layer 308 made of p-type GaAs.

The active layer 303 has a quantum well structure made of GaAs/Al_{0.59}Ga_{0.41}As of which the oscillation wavelength is 780 nm. The thickness of a well layer made of GaAs is preferably 6 nm or less as will be discussed later. In this embodiment, it is 3.7 nm, for example. The thickness of barrier layers made of Al_{0.59}Ga_{0.41}As sandwiching the well layer vertically is about 30 nm, for example. The active layer 303 includes only one well layer.

The n-type cladding layer 302 has a thickness of 3.3 μm, for example, and an impurity concentration of about 5×10¹⁷ cm⁻³. The p-type first cladding layer 304 has a thickness of 0.23 μm and an impurity concentration of about 7×10¹⁷ cm⁻³. The p-type second cladding layer 306 has a thickness of 1.5 μm, for example, and an impurity concentration of about 1×10¹⁸ cm⁻³.

The p-type second cladding layer 306 has a trapezoidal ridge that is to be a waveguide, extending straight in a direction parallel to the light emerging direction as viewed from above the substrate 101. The height of the ridge (distance from the p-type GaAs contact layer 308 to the p-type GaInP etching stop layer 305) is 1.5 μm, for example, and the width of the ridge is 4.5 μm, for example.

A current blocking layer 309 made of Si₃N₄ is formed on both side faces of the ridge and on the top of the etching stop layer 305, thereby to allow a current to flow only in the ridge.

A p-type electrode 310 constructed of a multilayer structure of Ti/Pt/Au layers, for example, is formed on the top of the p-type GaAs contact layer 308 and on the current blocking layer 309 to be in contact with these layers.

As the distance between the front and rear end facets of the active layer 303 (cavity length), 1500 μm or more is enough but 1700 μm or more is more preferred as will be discussed later. The cavity length of the CD laser element 103 is equal to the cavity length of the DVD laser element 102. Hence, the DVD laser element 102 and the CD laser element 103 can be formed simultaneously by a cleaving process and the like.

In this embodiment, the cavity length is set at four variations: 1500 μm, 2000 μm, 2200 μm, and 2350 μm. Light confinement is configured to have a horizontal spread angle of 8° and a vertical spread angle of 15°.

As described earlier, in the DVD laser element 102, to reduce the overflow of carriers thereby to suppress decrease in gain, x in the composition In_{y}(Ga₁₋ₓAlₓ)_{1-y}P(0<x<1, 0<y<1) of the cladding layers is set at 0.6≦x≦0.8. In addition, to enjoy the simplicity of the fabrication process of the dual-wavelength laser device, x in the composition of the cladding layers of the CD laser element 103 is also set at 0.6≦x≦0.8. Having the cladding layers common in composition, the DVD laser element 102 and the CD laser element 103 can be fabricated by a common fabrication process.

The chip width of the dual-wavelength laser device (length of the semiconductor chip in the direction that is vertical to the cavity direction and parallel to the principal plane of the substrate 101) is set at 230 μm, for example, and the thickness thereof (thickness from the p-type electrode 310 to the n-type electrode 104) is set at 100 μm, for example.

Both the front and rear cavity end facets of the elements are coated with a dielectric film (not shown). Since the dielectric film must be formed integrally over the entire dual-wavelength laser device, the type and thickness of the dielectric film is common to the DVD laser element 102 and the CD laser element 103. The reflectance of the front end facet from which laser light emerges is 8% for the DVD laser element 102 and 7% for the CD laser element 103. The reflectance of the rear end facet opposite to the front end facet is 90% for both laser elements

—Verification of Effect of Dual-wavelength Laser Device—

The present inventors performed some measurements described below to verify the effect of the dual-wavelength laser device of this embodiment.

As used herein, the CD laser element of the dual-wavelength laser device of Embodiment 1 is called “element A,” and a CD laser element of a dual-wavelength laser device prepared for comparison with the element A is called “element B.” The element B has the same configuration as the element A except that two well layers made of GaAs are provided in the active layer and that the thickness of the p-type first cladding layer is changed to have equal light confinement to that of the element A. The thickness of each well layer of the element B is 3.7 nm, which is the same as that of the well layer of the element A. To verify the specific effect of the present invention, the spread angles of the elements A and B are adjusted to have equal light confinement.

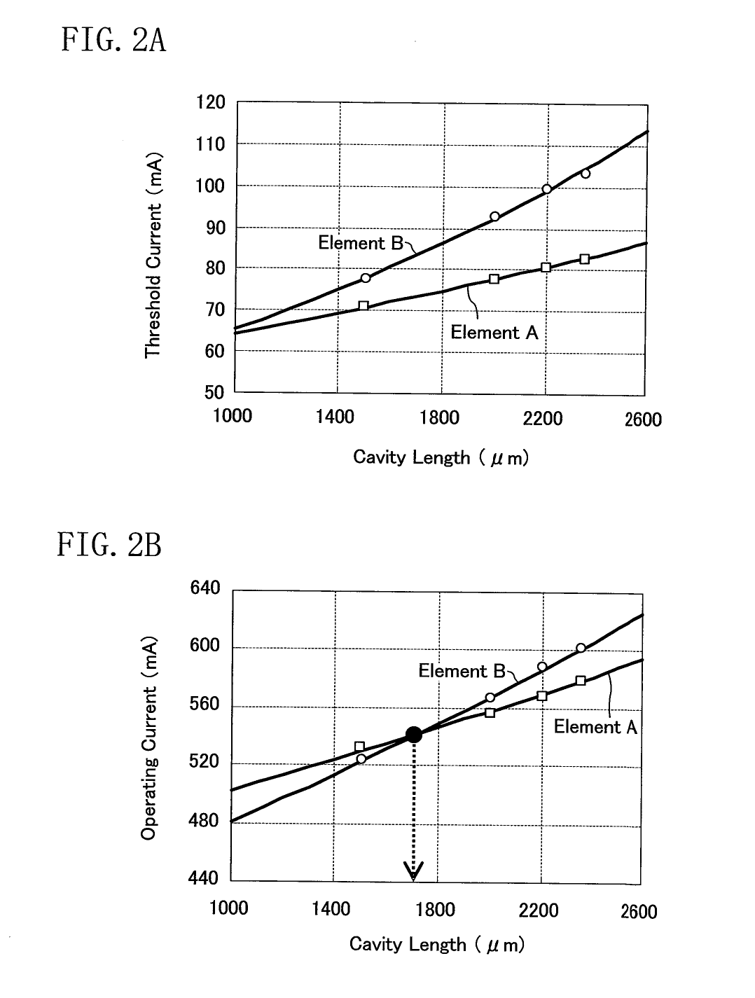

FIG. 2A shows calculation results of the relationship between the cavity length and the threshold current observed when the elements A and B are pulse-driven under the environment of a case temperature of 95° C.

It is found from the results shown in FIG. 2A that the threshold current can be kept lower in the element A having the active layer 303 of the single quantum well structure than in the element B when the cavity length is 1000 μm or more. While the threshold current increases with increase in cavity length in both the elements A and B, the rate of increase in threshold current is lower in the element A than in the element B. Hence, the longer the cavity length is, the greater the difference in threshold current between the elements A and B is.

FIG. 2B is a view showing measurement results of the relationship between the operating current and the cavity length observed when the elements A and B are pulse-driven to produce a light output of 400 mW under the environment of a case temperature of 95° C.

It is found from the results shown in FIG. 2B that, in the case of 400 mW pulse driving, the operating current is smaller in the element B than in the element A when the cavity length is less than 1700 μm. In other words, it is found that the power consumption of the element B is smaller than that of the element A. Conversely, the operating current is smaller in the element A than in the element B when the cavity length is 1700 μm or more. In other words, it is found that power consumption can be kept lower in the element A than in the element B. Hence, it can be concluded that the longer the cavity length is, the more advantageous the element A is in power consumption over the element B.

To ensure stable LightScribe operation, a light output of at least 400 mW or more is required. From the results described above, it is found that to perform LightScribe labeling with the element A, the cavity length is preferably 1700 μm or more from the standpoint of power consumption. Note that the light output is about 3 mW or less in normal disc read operation. The cavity length range within which the element A is more advantageous than the element B differs with the light output.

Considering the heat dissipation environment observed when a semiconductor laser device is mounted inside an optical pickup, the power consumption reducing effect of the element A as compared with the element B shown in FIG. 2B corresponds to about −8° C. in terms of temperature, for example, when the cavity length is 2200 μm.

From the comparison between the elements A and B described above, it is derived that the power consumption reducing effect, which is brought about by forming only one well layer in the active layer 303, is obtainable only when the cavity length is within a predetermined range. In the dual-wavelength laser device of this embodiment, it is only when the cavity length is 1700 μm or more that the power consumption reducing effect is obtainable in LightScribe operation. The above phenomenon is examined as follows.

(1) By forming only one well layer made of GaAs in the active layer 303, the threshold carrier density decreases, providing the effect of reducing the threshold current.

(2) Meanwhile, with only one GaAs well layer formed in the active layer 303, output saturation caused by gain saturation is likely to occur. This means that the efficiency of conversion of a current injected into the active layer 303 to light is likely to decrease. The output saturation tends to be relieved as the cavity length increases.

(3) The power consumption of the element A is determined by the sum of the power consumption reducing effect resulting from the reduction in threshold current (1) and the increase in power consumption caused by the output saturation (2).

(4) For a laser element having a cavity length of less than 1700 μm, the effect of (2) is dominant, and as a result, the power consumption of the element A is higher than that of the element B.

(5) On the contrary, for a laser element having a cavity length of 1700 μm or more, the effect of (2) is reduced, and as a result, the power consumption of the element A is lower than that of the element B.

As described above, in this embodiment, in the dual-wavelength laser device of which the cavity length is increased to optimize the performance of the DVD laser element, reduction in the power consumption of the CD laser element can be attained.

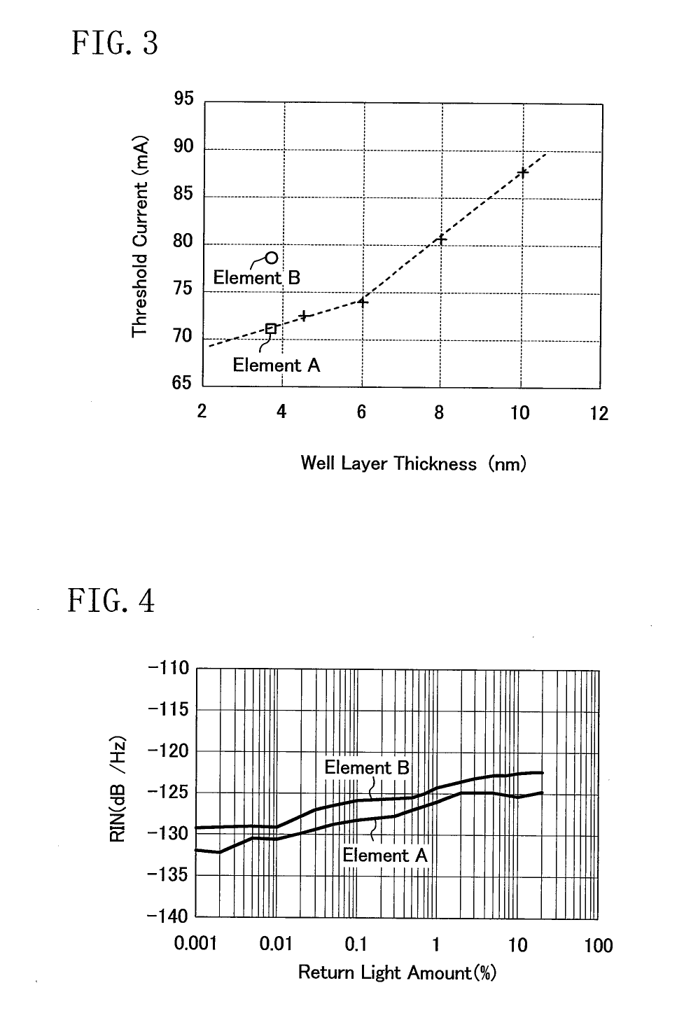

FIG. 3 is a view showing results of simulation of the relationship between the well layer thickness and the threshold current observed when the elements are pulse-driven under the environment of a case temperature of 95° C. The broken line in FIG. 3 shows the relationship between the thickness of the well layer constituting the active layer 303 of the element A and the threshold current observed when the cavity length is 1500 μm.

To stabilize the oscillation wavelength at 780 nm, it is necessary to use AlₓGa₁₋ₓAs (0<x<0.15) in place of GaAs, as the material of the well layer when the well layer thickness is 4 nm or more. As a result, the threshold current abruptly increases when the well layer thickness is more than 6 nm: it exceeds that of the element B when the well layer thickness is 7 nm or more. The increase in threshold current degrades noise characteristics. Hence, it is desirable to set the well layer thickness of the element A at 6 nm or less.

FIG. 4 is a view showing noise characteristics of the elements A and B observed when the cavity length is 1500 μm for both laser elements. The noise levels were measured with change in return light amount.

From the results shown in FIG. 4, it is confirmed that, with the reduction in the threshold current of the element A compared with that of the element B, the noise level decreased in the element A by about 3 dB/Hz compared with that in the element B. In the element A, therefore, it is considered that, if the well layer thickness is more than 6 nm, not only increase in threshold current but also degradation in noise characteristics will result.

A well layer thickness of 6 nm or less is also preferable from the following standpoint. In the CD laser element for CD recording and LightScribe labeling, normally, the degree of light confinement is adjusted so that the vertical spread angle is 15°. Specifically, since the refractive index of AlₓGa₁₋ₓAs (0≦x<1) constituting the active layer 303 including the well layer is higher than that of In_{1-y}(Ga₁₋ₓAlₓ)_{y}P (0<x<1, 0≦y≦1) constituting the n-type cladding layer 302, the p-type first cladding layer 304, and the p-type second cladding layer 306, the light distribution in the vertical direction is more concentrated in the well layer as the well layer becomes thicker, failing to obtain a desired vertical spread angle.

In the CD laser element of the dual-wavelength laser device of this embodiment, the n-type cladding layer 302, the p-type first cladding layer 304, and the p-type second cladding layer 306 may be made of AlₓGa₁₋ₓAs (0<x<1), in place of In_{1-y}(Ga₁₋ₓAlₓ)_{y}P (0<x<1, 0<y<1), to constitute the CD laser element. In this case, however, the efficiency of conversion of a current to light is not as high as that in the CD laser element in this embodiment. Hence, the cladding layers should preferably be made of In_{1-y}(Ga₁₋ₓAlₓ)_{y}P (0<x<1, 0<y<1) A larger band gap difference can be secured between the active layer and the cladding layers when using In_{1-y}(Ga₁₋ₓAlₓ)_{y}P (0<x<1, 0<y<1) as the cladding layers, and hence the current injected into the active layer can be converted to light efficiently. The efficiency of conversion of a current to light decreases as the temperature rises. Therefore, to secure a light output of 400 mW under the environment of a case temperature of 95° C., it is especially desirable to use In_{1-y}(Ga₁₋ₓAlₓ)_{y}P (0<x<1, 0<y<1) as the cladding layers.

As described above, in the dual-wavelength laser device of this embodiment, the power consumption of the CD laser element can be reduced even when a long cavity length is adopted to attain high output and when the device is operated at high temperature. Hence, the reliability can be enhanced compared with the conventional dual-wavelength laser devices.

Note that the dual-wavelength laser device of this embodiment can be fabricated by a known semiconductor fabrication technique.

### Embodiment 2

### Configuration of Dual-Wavelength Laser Device

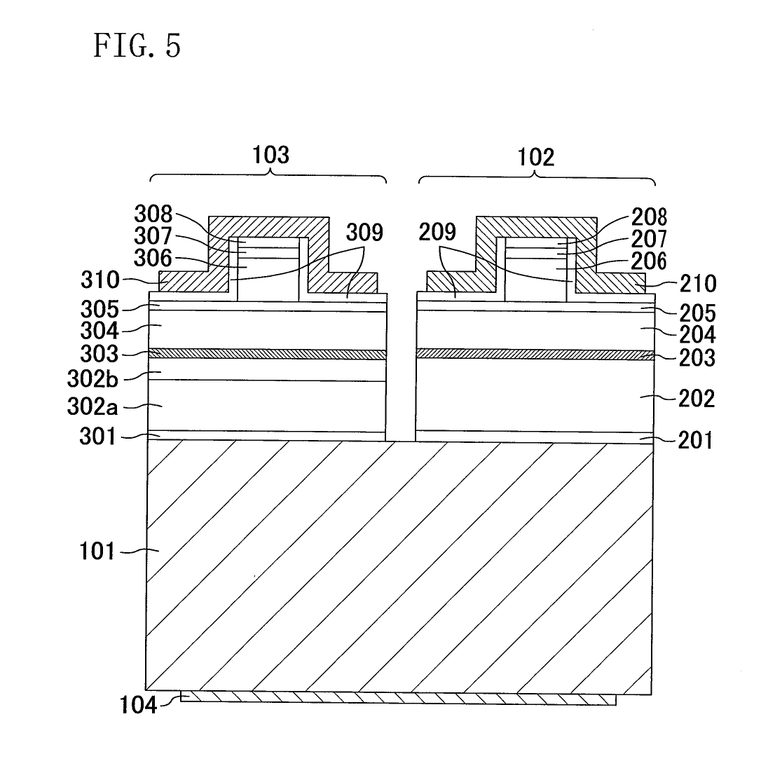

FIG. 5 is a cross-sectional view of a dual-wavelength laser device of Embodiment 2 of the present invention as viewed from the front end facet side. As shown in FIG. 5, the dual-wavelength laser device of this embodiment includes a DVD laser element 102 and a CD laser element 103 formed on a substrate 101 made of n-type GaAs. The configuration of the DVD laser element 102 is the same as that of the dual-wavelength laser device of Embodiment 1.

In the CD laser element 103, formed sequentially on the top of the n-type GaAs substrate 101 are a buffer layer 301 made of n-type GaAs, an n-type first cladding layer 302a made of n-type In_{0.5}(Ga_{0.32}Al_{0.68})_{0.5}P, an n-type second cladding layer 302b made of n-type In_{0.5}(Ga_{0.32}Al_{0.68})_{0.5}P, an active layer 303, a p-type first cladding layer 304 made of p-type In_{0.5}(Ga_{0.3}Al_{0.7})_{0.5}P, an etching stop layer 305 made of p-type GaInP, a p-type second cladding layer 206 made of p-type In_{0.5}(Ga_{0.32}Al_{0.68})_{0.5}P, an intermediate layer 307 made of p-type GaInP, and a contact layer 308 made of p-type GaAs.

The active layer 303 has a quantum well structure made of GaAs/Al_{0.59}Ga_{0.41}As which the oscillation wavelength is 780 nm. The thickness of a well layer made of GaAs is preferably 6 nm or less. In this embodiment, it is 3.7 nm, for example. The active layer 303 includes only one well layer.

The n-type first cladding layer 302a has a thickness of 2.8 for example, and an impurity concentration of about 5×10¹⁷ cm⁻³. The n-type second cladding layer 302b has a thickness of 0.5 μm, for example, and an impurity concentration of about 3×10¹⁷ cm⁻³. The p-type first cladding layer 304 has a thickness of 0.23 μm and an impurity concentration of about 7×10¹⁷ cm⁻³. The p-type second cladding layer 306 has a thickness of 1.5 μm, for example, and an impurity concentration of about 1×10¹⁸ cm⁻³.

The p-type second cladding layer 306 has a trapezoidal ridge that is to be a waveguide, extending straight in a direction parallel to the light emerging direction as viewed from above the substrate 101. The height of the ridge (distance from the p-type GaAs contact layer 308 to the p-type GaInP etching stop layer 305) is 1.5 μm, for example, and the width of the ridge is 4.5 μm, for example.

A current blocking layer 309 made of Si₃N₄ is formed on both side faces of the ridge and on the top of the etching stop layer 305, thereby to allow a current to flow only in the ridge.

A p-type electrode 310 made of a multilayer structure of Ti/Pt/Au layers, for example, is formed on the top of the p-type GaAs contact layer 308 and on the current blocking layer 309 to be in contact with these layers.

As the distance between the front and rear end facets of the active layer 303 (cavity length), 1500 μm or more is preferred, which is equal to the cavity length of the DVD laser element 102. Hence, the DVD laser element 102 and the CD laser element 103 can be formed simultaneously by a cleaving process and the like.

In this embodiment, the cavity length is set at four variations: 1500 μm, 2000 μm, 2200 μm, and 2350 μm. Light confinement is configured to have a horizontal spread angle of 8° and a vertical spread angle of 15°.

As described earlier, in the DVD laser element 102, to reduce the overflow of carriers thereby to suppress decrease in gain, x in the composition In_{y}(Ga₁₋ₓAlₓ)_{1-y}P (0<x<1, 0<y<1) of the cladding layers is set at 0.6≦x≦0.8. In addition, to enjoy the simplicity of the fabrication process of the dual-wavelength laser device, x in the composition of the cladding layers of the CD laser element 103 is also set at 0.6≦x≦0.8. Having the cladding layers common in composition, the DVD laser element 102 and the CD laser element 103 can be fabricated by a common fabrication process.

The chip width of the dual-wavelength laser device (length of the semiconductor chip in the direction that is vertical to the cavity direction and parallel to the principal plane of the substrate 101) is set at 230 μm, for example, and the thickness thereof is set at 100 μm, for example.

Both the front and rear cavity end facets of the elements are coated with a dielectric film (not shown). Since the dielectric film must be formed integrally over the entire dual-wavelength laser device, the type and thickness of the dielectric film is common to the DVD laser element 102 and the CD laser element 103. The reflectance of the front end facet from which laser light emerges is 8% for the DVD laser element 102 and 5% for the CD laser element 103. The reflectance of the rear end facet opposite to the front end facet is 90% for both laser elements

—Verification of Effect of Dual-Wavelength Laser Device—

The present inventors performed some measurements described below to verify the effect of the dual-wavelength laser device of this embodiment.

As used herein, the CD laser element of the dual-wavelength laser device of Embodiment 2 is called “element C”, and a CD laser element of a dual-wavelength laser device prepared for comparison with the element C is called “element D.” The element D has the same configuration as the element C except that two well layers made of GaAs are provided in the active layer 303. The thickness of each well layer of the element D is 3.7 nm, which is the same as that of the well layer of the element C. To verify the specific effect of the present invention, the spread angles of the elements C and D are adjusted to have equal light confinement.

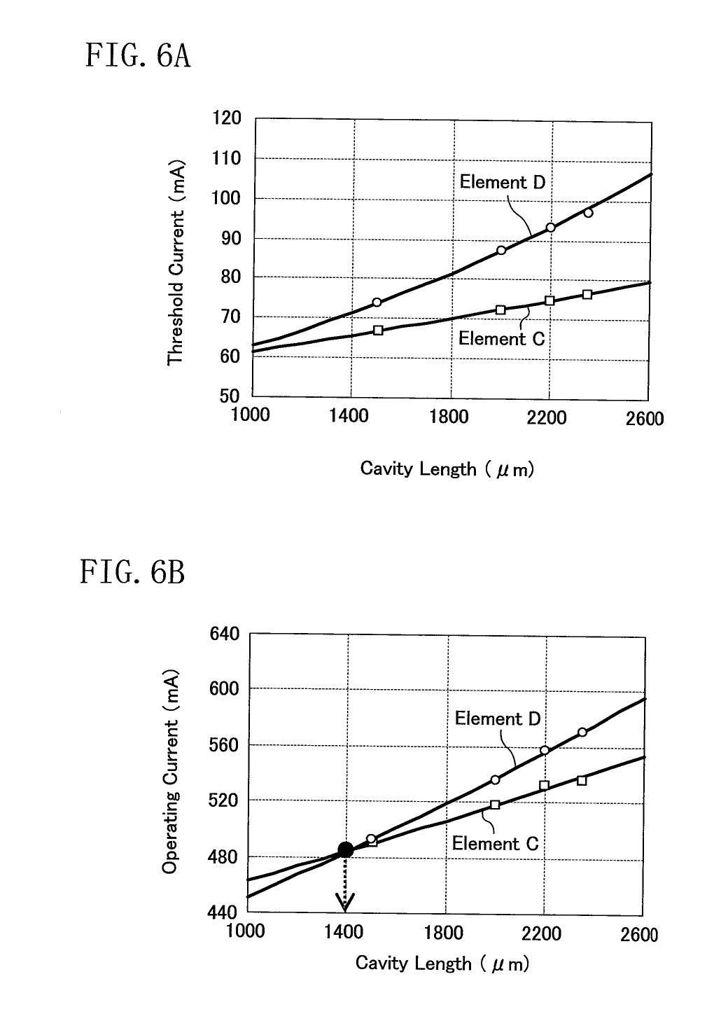

FIG. 6A shows calculation results of the relationship between the cavity length and the threshold current observed when the elements C and D are pulse-driven under the environment of a case temperature of 95° C.

It is found from the results shown in FIG. 6A that the threshold current can be kept lower in the element C having the active layer 303 of the single quantum well structure than in the element D when the cavity length is 1000 μm or more. While the threshold current increases with increase in cavity length in both the elements C and D, the rate of increase in threshold current is lower in the element C than in the element D. Hence, the longer the cavity length is, the greater the difference in threshold current between the elements C and D is.

FIG. 6B is a view showing measurement results of the relationship between the operating current and the cavity length observed when the elements C and D are pulse-driven to produce a light output of 400 mW under the environment of a case temperature of 95° C.

It is found from the results shown in FIG. 6B that, in the case of 400 mW pulse driving, the operating current is smaller in the element D than in the element C when the cavity length is less than 1400 μm. In other words, it is found that the power consumption of the element D is smaller than that of the element C. In reverse, the operating current is smaller in the element C than in element D when the cavity length is 1400 μm or more. In other words, it is found that the power consumption can be kept lower in the element C than in the element D. Hence, it is concluded that the longer the cavity length is, the more advantageous the element C is in power consumption over the element D.

Considering the heat dissipation environment observed when a semiconductor laser device is mounted inside an optical pickup, the power consumption reducing effect of the element C as compared with the element D shown in FIG. 6B corresponds to about −10° C. in terms of temperature, for example, when the cavity length is 2200 μm.

From the comparison between the elements C and D described above, it is derived that the power consumption reducing effect, which is brought about by forming only one well layer in the active layer 303, is obtainable only when the cavity length is within a predetermined range. In Embodiment 2, the power consumption reducing effect can be obtained only when the cavity length is 1400 μm or more.

In comparison of the CD laser element of this embodiment with the CD laser element of Embodiment 1, the lower limit of the cavity length until which the power consumption reducing effect can be obtained is smaller by about 300 μm. This will be examined by comparing the element A of Embodiment 1 with the element C of Embodiment 2.

The elements A and C are common in having a single well layer made of GaAs in the active layer 303 thereby to obtain the effect of reducing the threshold current.

The difference between the elements A and C is that, while the element A includes only the n-type cladding layer 302, the element C includes two n-type cladding layers, i.e., the n-type first cladding layer 302a and the n-type second cladding layer 302b, different in impurity concentration from each other. While the impurity concentration of the n-type second cladding layer 302b adjacent to the active layer 303 in the element C is 3×10¹⁷ cm⁻³the impurity concentration of the n-type cladding layer 302 in the element A is 5×10¹⁷ cm⁻³. Since free electrons generated from impurities implanted in a cladding layer have an effect of absorbing light, the absorption loss is considered to increase as the impurity concentration of the cladding layer increases.

Light generated in the active layer 303 is confined within a region including the active layer 303 in the center sandwiched by the n-type cladding layer and the p-type cladding layer. In general, in a CD laser element for CD recording and LightScribe labeling, the degree of light confinement is adjusted so that the vertical spread angle is 15°. In this case, 50% of the total light amount distributed in the n-type cladding layer 302 is confined in the range of 0.25 μm from the active layer 303, and 90% of the total light amount is confined in the range of 0.5 μm from the active layer 303.

Hence, in the element C, since 90% of light distributed in the n-type cladding layer exists in the n-type second cladding layer 302b that is comparatively low in impurity concentration, the absorption loss is considered lower than in the element A. As a result, it is considered that in the CD laser element in this embodiment, in which the active layer includes only one well layer, the problem of output saturation caused by gain saturation is relieved.

The absorption loss can be further reduced as the impurity concentration of the n-type second cladding layer 302b of the element C becomes lower. However, if having an excessively low impurity concentration, the n-type second cladding layer 302b will become a barrier layer against carriers, blocking carrier injection from the n-type electrode 104 into the active layer, and hence lowering the efficiency of conversion of the current to light. In the element C, the power consumption increased when the impurity concentration of the n-type second cladding layer 302b was 2×10¹⁷ cm⁻³. Hence, the impurity concentration of the n-type second cladding layer 302b is preferably 2×10¹⁷ cm⁻³ or higher.

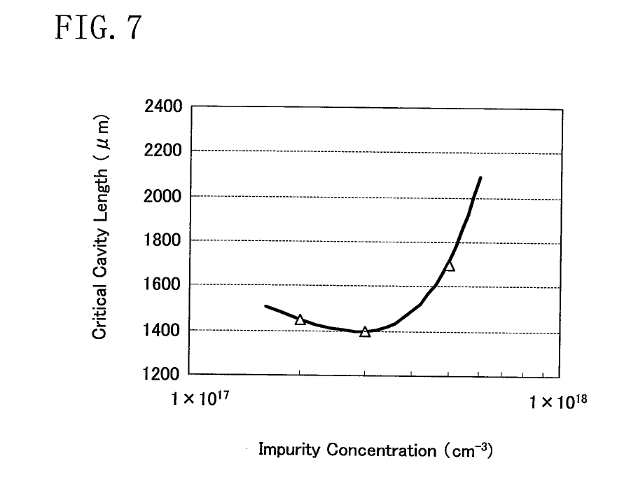

FIG. 7 is a view showing the relationship between the minimum cavity length at which the power consumption of the CD laser element in this embodiment having only one well layer in the active layer 303 becomes lower than that of the CD laser element of a comparative example having two well layers (hereinafter referred to as the critical cavity length) and the impurity concentration of the n-type second cladding layer 302b. Measurement of the power consumption was made under the condition of pulse-driving the element to produce a light output of 400 mW under the environment of a case temperature of 95°, which is required to ensure stable LightScribe operation.

From the results shown in FIG. 7, it is found that the critical cavity length is smallest when the impurity concentration of the n-type second cladding layer 302b is 3×10¹⁷ cm⁻³. Hence, as long as the cavity length is 1400 pin or more, the power consumption of the CD laser element is lower than that of the CD laser element of the comparative example.

In the element C, the thickness of the n-type second cladding layer 302b low in impurity concentration may be more than 0.5 μm. However, since 90% of the total light amount distributed in the n-type second cladding layer 302b is confined in the range of 0.5 μm from the first active layer 303, the effect of reducing output saturation caused by gain saturation will be limited even if the thickness of the n-type second cladding layer 302b is increased to more than 0.5 μm. On the contrary, if the layer low in impurity concentration is excessively thick, the bulk resistance of the cladding layer will rise, causing increase in the heat dissipation of the element and as a result increase in the power consumption of the element. Hence, the thickness of the n-type second cladding layer 302b is preferably about 1.5 μm or less.

Like the impurity concentration of the n-type second cladding layer 302b, the impurity concentration of the p-type first cladding layer 304 may be made lower (than that of the p-type second cladding layer 306, for example). In this case, also, light absorption by free electrons can be reduced, reducing output saturation. When the degree of light confinement is adjusted so that the vertical spread angle is 15° in the CD laser element, 50% of the total light amount distributed in the p-type first cladding layer 304 is confined in the range of 0.1 μm from the active layer 303, and 90% of the total light amount is confined in the range of 0.2 μm from the active layer 303.

As the p-type impurity used for the p-type first cladding layer 304, Zn and Mg are normally used. Such impurity materials are significantly large in diffusion coefficient compared with n-type impurity materials. Since two types of double-hetero structures are formed in a dual-wavelength laser device, the double-hetero structure formed first, in particular, is exposed to high temperature during epitaxy for a long time. In this situation, the large diffusion coefficient of the p-type impurity cannot to be neglected. If the impurity concentration of the p-type first cladding layer 304 is higher than 7×10¹⁷ cm⁻³, impurity diffusion into the active layer 303 may seriously affect the reliability of the element. Hence, the impurity concentration (p-type impurity concentration) of at least a region from the active layer 303 toward the p-type first cladding layer 304 is desirably 7×10¹⁷ cm⁻³ or less.

As described above, in the dual-wavelength laser device of this embodiment, the cavity length is made long to optimize the performance of the DVD laser element, and the power consumption of the CD laser element can be reduced.

As described above, to implement a DVD laser element having an output of 300 mW or more, the cavity length of the dual-wavelength laser device must be 1500 μm or more. With the cavity length of 1500 μm or more, the CD laser element is configured to have only one well layer. With this configuration, by designing the element considering the bulk resistance and absorption loss that depend on the impurity densities of the cladding layers, high-output operation with good noise characteristics and low power consumption can be attained.

Also, in the configuration of the dual-wavelength laser device of an example of the present invention, by setting the impurity concentration of the n-type cladding layer within the range of 2×10¹⁷ cm⁻³ to 5×10¹⁷ cm⁻³, even the CD laser element can exhibit good noise characteristics at an output of 400 mW under a temperature as high as 95° C. when the cavity length is 1700 μm or more.

Accordingly, using the dual-wavelength laser device of an example of the present invention, it is possible to enhance the quality of playback/recording from/on an optical disc without the necessity of providing a heat dissipation mechanism or a return light antinoise mechanism redundantly in the optical pickup.

It is to be understood that the foregoing embodiments are mere examples of embodiments of the present invention, and that various changes may be made to all the components of the embodiments, including the material, thickness, and shape of each part, without departing from the spirit of the present invention.

As described above, the dual-wavelength laser devices of illustrative embodiments of the present invention are compatible to both DVD dual-layer recording and LightScribe labeling, and hence usable as light sources of a variety of DVD/CD recording/playback apparatuses and the like.

What is claimed is:

1. A semiconductor laser device, comprising:
a first semiconductor laser element; and
a second semiconductor laser element different in oscillation wavelength from the first semiconductor laser element, formed in a same substrate as the first semiconductor laser element,
wherein
the first semiconductor laser element and the second semiconductor laser element have the same cavity length, which is 1500 μm or more,
the first semiconductor laser element and the second semiconductor laser element each have an n-type cladding layer made of In_{y}(Ga₁₋ₓ₁Alₓ₁)_{1-y}P (0<x1 <1, 0<y<1) and a p-type cladding layer made of In_{y}(Ga₁₋ₓ₂Alₓ₂)_{1-y}P (0<x2 <1, 0<y<1) and the first semiconductor laser element has a first active layer that is made of Al_{z}Ga_{1-z}As (0≦z≦1), is placed between the n-type cladding layer and the p-type cladding layer, and includes only one first well layer.

2. The semiconductor laser device of claim 1, wherein the first semiconductor laser element has the first active layer including the first well layer made of an AlGaAs material and a first barrier layer larger in band gap energy than the first well layer, and
the second semiconductor laser element has a second active layer including a second well layer made of an InGaAlP material and a second barrier layer larger in band gap energy than the second well layer.

3. The semiconductor laser device of claim 2, wherein the oscillation wavelength range of the first semiconductor laser element is a 780 nm band, and the oscillation wavelength range of the second semiconductor laser element is a 660 nm band.

4. The semiconductor laser device of claim 3, wherein the first well layer has a thickness of 6 nm or less and a composition of Al_{z}Ga_{1-z}As where 0≦z≦0.15.

5. The semiconductor laser device of claim 4, wherein x1 in the composition of the n-type cladding layer is 0.6≦x1 ≦0.8, and x2 in the composition of the p-type cladding layer is 0.6≦x2≦0.8.

6. The semiconductor laser device of claim 5, wherein a region of the n-type cladding layer of the first semiconductor laser element having a thickness of at least 0.5 μm adjacent to the first active layer has an impurity concentration in the range of 2×10¹⁷ cm⁻³ to 3×10¹⁷ cm⁻³.

7. The semiconductor laser device of claim 6, wherein the n-type cladding layer of the first semiconductor laser element has an n-type first cladding layer and an n-type second cladding layer lower in impurity concentration than the n-type first cladding layer sandwiched between the n-type first cladding layer and the first active layer.

8. The semiconductor laser device of claim 1, wherein the cavity length of the first semiconductor laser element and the second semiconductor laser element is 1700 μm or more.

9. The semiconductor laser device of claim 8, wherein a region of the n-type cladding layer of the first semiconductor laser element having a thickness of at least 0.5 μm adjacent to the first active layer has an impurity concentration in the range of 2×10¹⁷ cm⁻³ to 5×10¹⁷ cm⁻³.
